(19) United States
(12) Patent Application Publication
(10) Pub. No.: US 2005/0016582 A1
(43) Pub. Date: Jan. 27, 2005

(54) Solar cell and method of manufacturing the same

(76) Inventors: Yoo Jin Lee, Seoul (KR); Jin Koog Shin, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(21) Appl. No.: 10/733,261

(22) Filed: Dec. 12, 2003

(30) Foreign Application Priority Data
Jul. 22, 2003 (KR) 2003-50215

(51) Int. Cl. H01L 31/00

(52) U.S. Cl. 136/255; 438/57

(57) ABSTRACT

The present invention relates to a solar cell and a method of manufacturing the same wherein a deterioration phenomenon can be eliminated. The solar cell comprises a solar cell device region constructed by sequentially stacking a first electrode, a P-type semiconductor layer, an intrinsic absorber, an N-type semiconductor layer and a second electrode on a substrate; an insulating film formed on the second electrode; and a thin film heater pattern formed on the insulating film. According to the present invention, there is advantages in that a phenomenon of deterioration of properties of a thin film due to the Staebler-Wronski effect can be eliminated in such a manner that a thin film heater is mounted within the solar cell and then supplied with a current or voltage to cause the solar cell to be subjected to heat treatment after the solar cell has been exposed to light for a long time.

### BACKGROUND OF THE INVENTION

1. Field of the Invention

The present invention relates to a solar cell and a method of manufacturing the same wherein a deterioration phenomenon can be eliminated, and more particularly, to a solar cell and a method of manufacturing the same wherein a phenomenon of deterioration of properties of a thin film due to the Staebler-Wronski effect (hereinafter, referred to as “S-W effect”) can be eliminated in such a manner that a thin film heater is mounted within the solar cell and then supplied with a current or voltage to cause the solar cell to be subjected to heat treatment after the solar cell has been exposed to light for a long time.

2. Description of the Related Art

Solar cells have lately been put to practical use and a variety of researches and developments for the solar cells have been conducted.

For the full-scale use of solar cells, it is particularly important to pursue economy of resources and low costs. Further, it is preferred that thin solar cells be used rather than thick solar cells in view of the efficiency of energy conversion (photovoltaic energy conversion).

FIG. 1 is a view conceptually illustrating the driving of a general solar cell. Referring to the figure, a P-type semiconductor layer 1 and an N-type semiconductor layer 2 are bonded to each other, an electrode pad 3a is then formed on the bottom of the P-type semiconductor layer 1, and another electrode pad 3b is formed on the N-type semiconductor layer 2. Accordingly, the solar cell 5 is roughly completed.

If a lamp 6 is connected to the electrode pads 3a and 3b of the solar cell 5 and sunlight is then irradiated on the solar cell 5, an electromotive force is generated due to the photovoltaic effect by which a current flows across the N-type and P-type semiconductor layers 2 and 1. Thus, electric energy is generated and the lamp 6 is lighted.

Most of such solar cells are mass-produced from silicon single-crystal or polycrystalline wafers. In addition, thin film semiconductors made of microcrystalline, nanocrystalline or amorphous silicon and compounds such as GaAs have been employed in solar cells.

Meanwhile, great progress has been made through continuous researches in amorphous silicon thin films widely used for solar cells since 1980s, including the fact that their energy conversion efficiencies reach about 14%. However, there is still a deterioration phenomenon due to light, i.e. S-W effect, when the thin films are exposed to sunlight. Therefore, attempts to eliminate the S-W effect have been made continuously.

Here, the S-W effect is a phenomenon that photoconductivity and dark conductivity of amorphous silicone are deteriorated with time when the amorphous silicon is exposed to light.

In order to solve such a problem of the deterioration of the properties of the amorphous silicon solar cell due to the S-W effect, efforts to minimize the deterioration of the properties by optimizing thin film material and device design have been made heretofore.

That is, methods of reducing the S-W effect are as follows:
1. A method of reducing the thickness of an intrinsic absorber as much as possible in order to maintain a high electric field after deterioration;
2. A method of assisting the movement of minority carriers in a low field region by adjusting a band-gap of an intrinsic absorber;
3. A method of adjusting an impurity doping level;
4. A method of stacking layers with different carrier mobilities on above another; and
5. A method of manufacturing a solar cell with multi-junctions by repeating a P layer-intrinsic absorber-N layer structure.

The aforementioned conventional methods cannot fundamentally solve the problem of S-W effect but can merely reduce the deterioration.

Accordingly, even though thin film material or device design is optimized, it is not possible to solve the property deterioration phenomenon due to the S-W effect.

### SUMMARY OF THE INVENTION

The present invention is conceived to solve the aforementioned problems. An object of the present invention is to provide a solar cell and a method of manufacturing the same wherein a phenomenon of deterioration of properties of a thin film due to the S-W effect can be eliminated in such a manner that a thin film heater is mounted within the solar cell and then supplied with a current or voltage to cause the solar cell to be subjected to heat treatment after the solar cell has been exposed to light for a long time.

According to one aspect of the present invention for achieving the object, there is provided a solar cell comprising a solar cell device region constructed by sequentially stacking a first electrode, a P-type semiconductor layer, an intrinsic absorber, an N-type semiconductor layer and a second electrode on a substrate; an insulating film formed on the second electrode; and a thin film heater pattern formed on the insulating film.

According to another aspect of the present invention, there is provided a method of manufacturing a solar cell, comprising the steps of sequentially stacking a first electrode, a P-type semiconductor layer, an intrinsic absorber, an N-type semiconductor layer and a second electrode on a substrate; forming an insulating film on the second electrode; forming a metal layer on the insulating film, and forming a thin film heater pattern composed of the metal layer by performing photolithography; forming a protection film on the insulating film and the thin film heater pattern; forming a pair of contact holes by removing portions of the protection film above both side ends of the thin film heater pattern; and filling conductive material into the contact holes and forming a pair of electrode pads to be electrically connected to the conductive material in the contact holes.

### BRIEF DESCRIPTION OF THE DRAWINGS

The above and other objects, features and advantages of the present invention will become apparent from the following description of preferred embodiments given in conjunction with the accompanying drawings, in which:

FIG. 1 is a view conceptually illustrating the driving of a general solar cell;

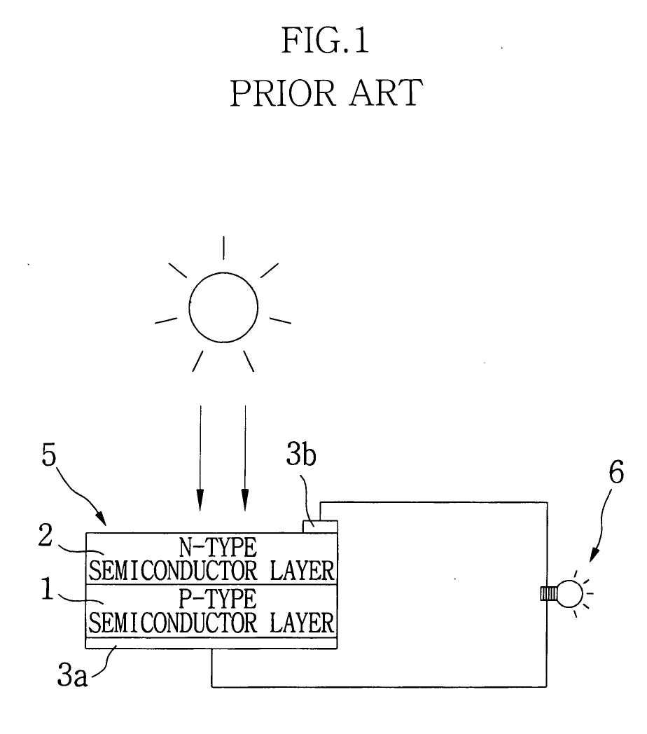

FIG. 2 is an exploded perspective view schematically showing a silicon solar cell with a thin film heater contained therein according to the present invention;

FIGS. 3a to 3d are views showing the manufacturing process of forming the thin film heater on a solar cell device according to the present invention;

FIG. 4 is a sectional view showing another structure of P-I-N semiconductor layers of the solar cell device according to the present invention; and

FIG. 5 is a plan view schematically showing a thin film pattern and thermocouple patterns formed in the solar cell device according to the present invention.

### DETAILED DESCRIPTION OF THE INVENTION

Hereinafter, preferred embodiments of the present invention will be described in detail with reference to the accompanying drawings.

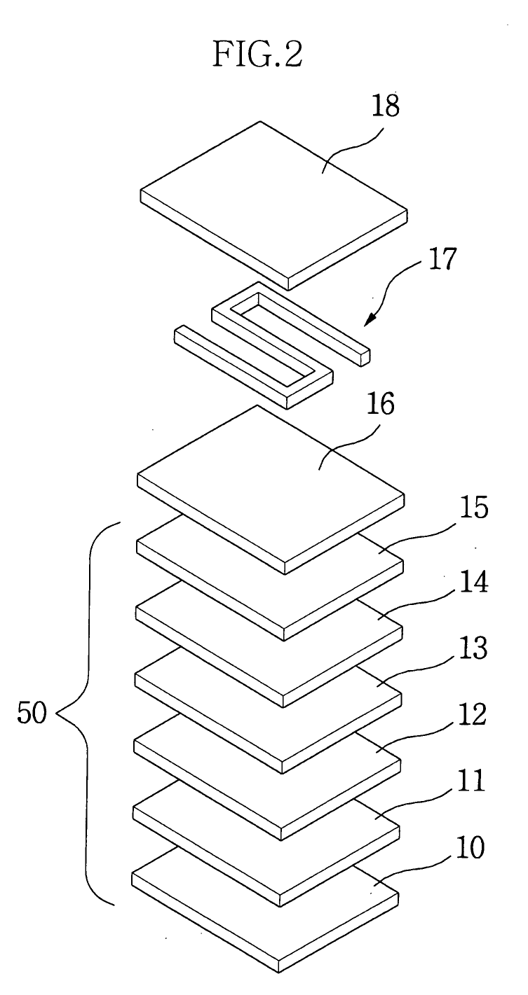

FIG. 2 is an exploded perspective view schematically showing a silicon solar cell with a thin film heater contained therein according to the present invention. Referring to the figure, a first electrode 11, a P-type semiconductor layer 12, an intrinsic absorber 13, an N-type semiconductor layer 14, a second electrode 15 and an insulating film 16 are sequentially stacked on a substrate 10. Further, a thin film heater pattern 17 is formed on the insulating film 16, and a protection film 18 is formed on the insulating film 16 and the thin film heater pattern 17.

At this time, the intrinsic absorber 13 is a non-doped amorphous silicon layer, and the P-type and N-type semiconductor layers 12 and 14 are amorphous silicon layers doped with P-type and N-type impurities, respectively.

Here, the stacked structure from the substrate 10 to the second electrode 15 is a basic solar cell device region 50 serving as a solar cell.

The stacked structure from the insulating film 16 to the protection film 18 is a structure for mounting a thin film heater on the solar cell device in accordance with the present invention.

Further, it is preferred that the substrate 10 be formed of any one of plastic, silicon and glass.

At this time, if the substrate 10 is formed of plastic or silicon, the first electrode 11 is formed of metal, the second electrode 15 is formed of a transparent conducting oxide (TCO) such as ITO, ZnO or SnO₂, and the solar cell device is implemented with a superstrate structure that receives sunlight from the second electrode 15.

Further, if the substrate 10 is formed of metal, the substrate 10 can be used as an electrode. Thus, the formation of the first electrode can be omitted, and the superstrate solar cell device is implemented as described above.

Meanwhile, if the substrate 10 is formed of glass, the first electrode 11 is formed of TCO, the second electrode 15 is formed of metal, and the solar cell is implemented with a substrate structure that receives sunlight from the first electrode 11.

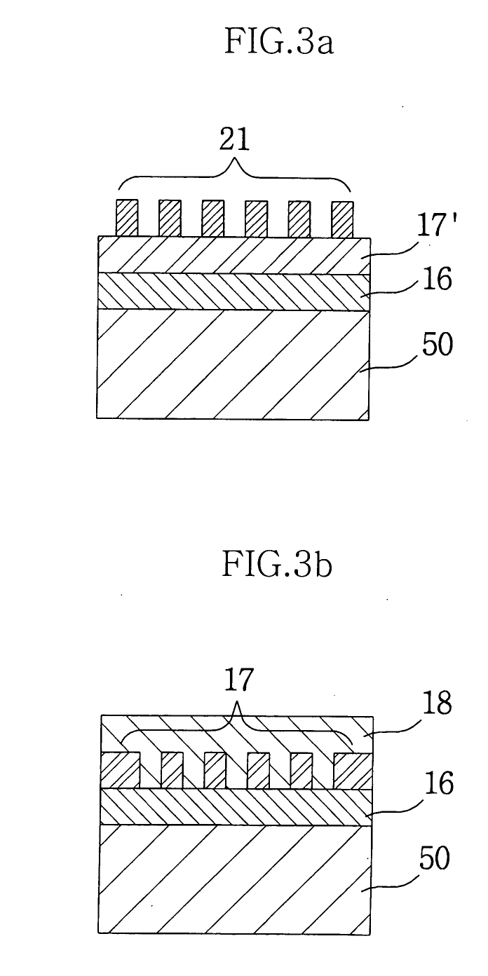

FIGS. 3a to 3d are views showing the manufacturing process of forming the thin film heater on the solar cell device according to the present invention. The insulating film 16 is first formed on the solar cell device region, a metal layer 17′ for forming a thin film heater is formed on the insulating film 16, and a photoresist pattern 21 is then formed on the metal layer 17′ (see FIG. 3a).

Thereafter, the metal layer 17′ is etched to form the thin film heater pattern 17 by using the photoresist pattern 21 as a mask, and the protection film 18 is then formed on the insulating film 16 and the thin film heater pattern 17 (see FIG. 3b).

Accordingly, the thin film heater pattern 17 is formed by means of photolithography as described above.

Subsequently, portions of the protection film 18 above both side ends of the thin film heater pattern 17 are removed to form a pair of contact holes 25a and 25b (see FIG. 3c).

Finally, after conductive material is filled into the contact holes 25a and 25b, a pair of electrode pads 31a and 31b are formed to be electrically connected to the conductive material in the contact holes 25a and 25b, respectively (see FIG. 3d).

As described above, the present invention can fundamentally overcome the S-W effect by installing the thin film heater within the solar cell to perform heat treatment.

More specifically, in order to eliminate the deterioration phenomenon of the amorphous silicon (i.e. S-W effect) that occurs in a solar cell exposed to sunlight for a long time, the amorphous silicon layer is heat-treated at a temperature in the range of 100 to 500° C. for 1 to 3 hours using resistance heat generated upon applying a current or voltage to the thin film heater, so that the deteriorated amorphous silicon can be recovered to the original state.

Here, it is preferred that the heating temperature range be 120 to 300° C.

Therefore, the present invention has advantages in that since the deteriorated amorphous silicon is recovered to the original state, the properties of the thin film can be improved and reduction in the efficiency of the solar cell can be prevented.

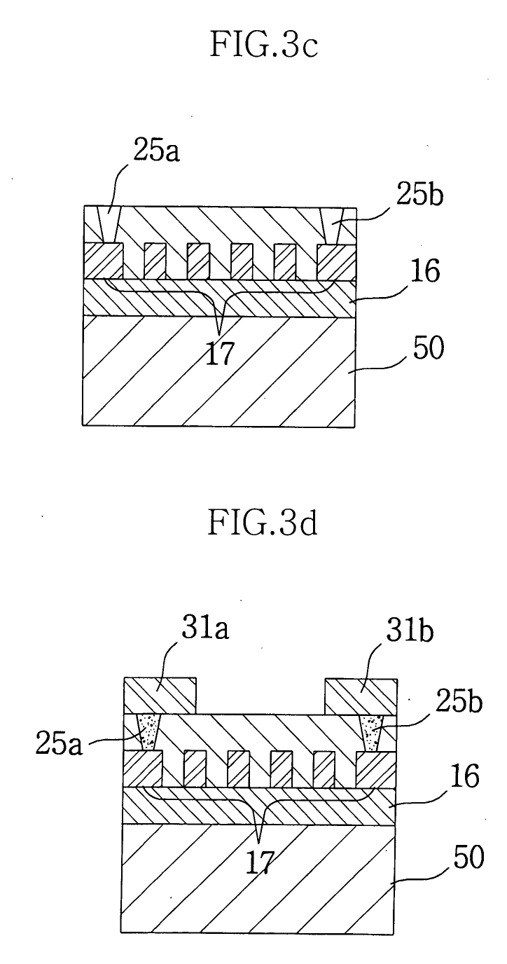

FIG. 4 is a sectional view showing another structure of P-I-N semiconductor layers of the solar cell device according to the present invention, wherein a second P-I-N (P-type/intrinsic/N-type) semiconductor layer 104, 105 and 106 formed of crystalline silicon is stacked on a first P-I-N (P-type/intrinsic/N-type) semiconductor layer 101, 102 and 103 formed of amorphous silicon.

At this time, it is preferred that the respective layers of the first P-I-N (P-type/intrinsic/N-type) semiconductor layer 101, 102 and 103 be formed to have thicknesses relatively smaller than those of the corresponding layers of the second P-I-N (P-type/intrinsic/N-type) semiconductor layers 104, 105 and 106.

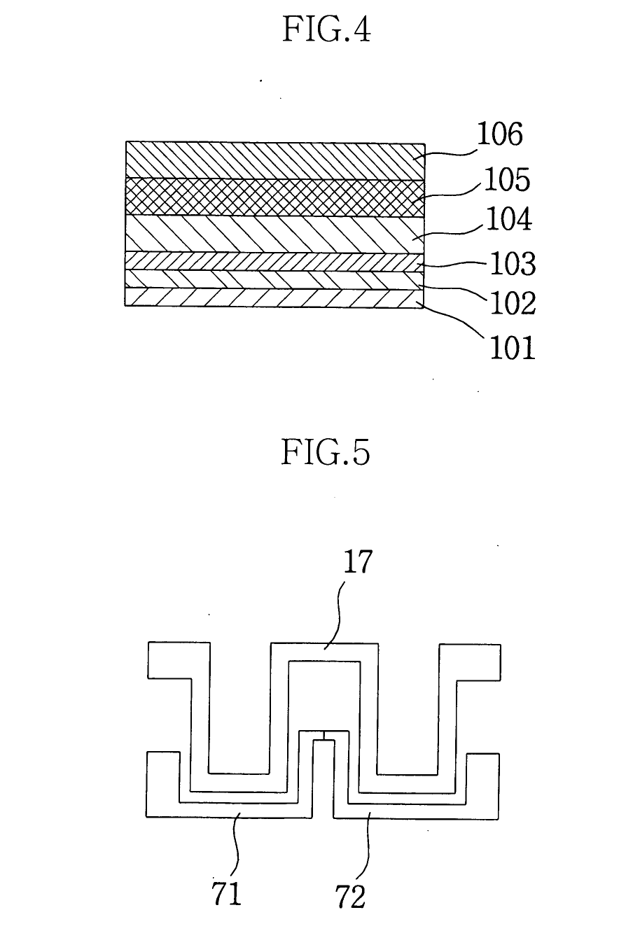

FIG. 5 is a plan view schematically showing the thin film pattern and thermocouple patterns formed in the solar cell device according to the present invention. Referring to this figure, thermocouple patterns 71 and 72 having two electrode terminals are formed between relevant portions of the thin film heater pattern 17 to measure a temperature elevated by the thin film heater, thereby controlling the temperature.

That is, the present invention is characterized in that a temperature-measuring device such as the thermocouple is additionally formed between the relevant portions of the thin film heater pattern 17.

According to the present invention described above, there is advantages in that a phenomenon of deterioration of properties of a thin film due to the Staebler-Wronski effect (hereinafter, referred to as “S-W effect”) can be eliminated in such a manner that a thin film heater is mounted within the solar cell and then supplied with a current or voltage to cause the solar cell to be subjected to heat treatment after the solar cell has been exposed to light for a long time.

Although the present invention has been described in connection with the preferred embodiments thereof, it will be apparent to those skilled in the art that various changes and modifications can be made thereto without departing from the scope and spirit of the present invention defined by the appended claims. Therefore, such changes and modifications fall within the scope of the invention.

1. A solar cell, comprising:
a solar cell device region constructed by sequentially stacking a first electrode, a P-type semiconductor layer, an intrinsic absorber, an N-type semiconductor layer and a second electrode on a substrate;
an insulating film formed on the second electrode; and
a thin film heater pattern formed on the insulating film.

2. The solar cell as claimed in claim 1, further comprising a protection film formed on the insulating film and the thin film heater pattern to protect the thin film heater pattern from the outside.

3. The solar cell as claimed in claim 1, wherein the intrinsic absorber is a non-doped amorphous silicon layer, and the P-type and N-type semiconductor layers are amorphous silicon layers doped with P-type and N-type impurities, respectively.

4. The solar cell as claimed in claim 3, further comprising another stacked structure between the N-type semiconductor layer and the second electrode, the stacked structure being constructed by sequentially stacking a P-type crystalline silicon layer, a non-doped crystalline silicon layer and an N-type crystalline silicon layer one above another.

5. The solar cell as claimed in claim 4, wherein the P-type amorphous silicon layer, the non-doped amorphous silicon layer and the N-type amorphous silicon layer are formed to have thicknesses smaller than those of the corresponding P-type crystalline silicon layer, non-doped crystalline silicon layer and N-type crystalline silicon layer, respectively.

6. The solar cell as claimed in claim 1, further comprising a device for measuring a temperature elevated by the thin film heater pattern, between relevant portions of the thin film heater pattern.

7. The solar cell as claimed in claim 6, wherein the temperature-measuring device is a thermocouple.

8. The solar cell as claimed in claim 1, wherein the substrate is formed of any one of plastic, silicon and glass.

9. The solar cell as claimed in claim 1, wherein the substrate is formed of plastic or silicon, the first electrode is formed of metal, and the second electrode is formed of a transparent conducting oxide (TCO).

10. The solar cell as claimed in claim 1, wherein the substrate is formed of glass, the first electrode is formed of a transparent conducting oxide (TCO), and the second electrode is formed of metal.

11. A solar cell, comprising:
a solar cell device region constructed by sequentially stacking a P-type semiconductor layer, an intrinsic absorber, an N-type semiconductor layer and an electrode on a substrate formed of metal;
an insulating film formed on the electrode;
a thin film heater formed on the insulating film; and
a protection film for protecting the thin film heater from the outside.

12. A method of manufacturing a solar cell, comprising the steps of:
sequentially stacking a first electrode, a P-type semiconductor layer, an intrinsic absorber, an N-type semiconductor layer and a second electrode on a substrate;
forming an insulating film on the second electrode;
forming a metal layer on the insulating film, and forming a thin film heater pattern composed of the metal layer by performing photolithography;
forming a protection film on the insulating film and the thin film heater pattern;
forming a pair of contact holes by removing portions of the protection film above both side ends of the thin film heater pattern; and
filling conductive material into the contact holes and forming a pair of electrode pads to be electrically connected to the conductive material in the contact holes.

13. The method as claimed in claim 12, wherein the intrinsic absorber is a non-doped amorphous silicon layer, and the P-type and N-type semiconductor layers are amorphous silicon layers doped with P-type and N-type impurities, respectively.

14. The method as claimed in claim 13, further comprising the step of forming another stacked structure between the N-type semiconductor layer and the second electrode, the stacked structure being constructed by sequentially stacking a P-type crystalline silicon layer, a non-doped crystalline silicon layer and an N-type crystalline silicon layer one above another.
